(19) United States
(12) Patent Application Publication
(10) Pub. No.: US 2021/0102042 A1
(43) Pub. Date: Apr. 8, 2021

(54) FILLER POWDER AND METHOD FOR PRODUCING SAME

(71) Applicant: NIPPON ELECTRIC GLASS CO., LTD., Otsu-shi, Shiga (JP)

(72) Inventor: Masashi NAKAMURA, Otsu-shi (JP)

(21) Appl. No.: 16/635,211

(22) PCT Filed: Jul. 30, 2018
(86) PCT No.: PCT/JP2018/028478

§ 371 Date: Jan. 30, 2020

(30) Foreign Application Priority Data
Aug. 29, 2017 (JP) 2017-164054

(51) Int. Cl. C08K 3/40; C08K 7/20; C03C 25/002; C03B 20/00

(52) U.S. Cl. CPC C08K 3/40; C08K 7/20; C08K 2201/005; C03B 20/00; C03C 25/002

(57) ABSTRACT

Provided is a filler powder that has a lower coefficient of thermal expansion than silica powder and can provide a resin composition having an excellent light transmittance. The filler powder is made of a crystallized glass with β-quartz solid solution and/or β-eucryptite precipitated therein, wherein a ratio D90/D10 between a 10% cumulative particle diameter (D10) and a 90% cumulative particle diameter (D90) both obtained by measuring a particle size distribution of the filler powder by a laser diffraction and scattering method is 20 or less.

### TECHNICAL FIELD

The present invention relates to a filler powder suitable to be mixed into a resin for use in sealing an optical semiconductor and so on and a method for producing the same.

### BACKGROUND ART

An optical semiconductor, such as a light-emitting diode, a laser diode or a phototransistor, is made of a compound semiconductor, such as GaAs or InP, is very sensitive to mechanical or thermal shock and changes in atmosphere, and therefore may be easily damaged. In order to prevent this, such an optical semiconductor is sealed with a transparent resin, such as epoxy resin. However, a difference in coefficient of thermal expansion between the resin and a substrate having the optical semiconductor mounted thereon and sealed with the resin promotes the occurrence of cracks. Therefore, the coefficient of thermal expansion of the resin needs to be decreased. For this reason, an inorganic filler powder, such as silica powder, is mixed into the resin. Silica powder is widely used as an inorganic filler powder because it has excellent physical strength and thermal resistance (see, for example, Patent Literature 1).

### CITATION LIST

### Patent Literature

### [PTL 1]

### JP-A-2009-88303

### SUMMARY OF INVENTION

### Technical Problem

In recent years there has been a demand for further reduction in thermal expansion of resin compositions. Silica powder has a low coefficient of thermal expansion to some degree, but its effect of decreasing the coefficients of thermal expansion of resin compositions is still insufficient. Therefore, even if silica powder is mixed into a resin, the resin composition is less likely to achieve a desired low coefficient of thermal expansion. Alternatively, if in order to achieve a desired low coefficient of thermal expansion a large amount of silica powder is mixed into the resin, the resin composition tends to decrease the homogeneity or have poor smoothness when formed into a film

It is conceivable to use a filler powder made of β-eucryptite crystal, β-quartz solid solution crystal or the like exhibiting a lower expansion characteristic than silica powder, in which case the filler powder may react with the resin composition to alter the quality or color of the resin composition. Furthermore, there arises a problem that when these types of filler powder are added to a resin, the light transmittance of the resin composition decreases, so that the light extraction efficiency of the optical semiconductor decreases.

In view of the above, the present invention has an object of providing a filler powder that has a lower coefficient of thermal expansion than silica powder and can provide a resin composition having an excellent light transmittance.

### Solution to Problem

A filler powder according to the present invention is made of a crystallized glass with β-quartz solid solution and/or β-eucryptite precipitated therein, wherein a ratio D90/D10 between a 10% cumulative particle diameter (D10) and a 90% cumulative particle diameter (D90) both obtained by measuring a particle size distribution of the filler powder by a laser diffraction and scattering method is 20 or less. Since the filler powder according to the present invention is made of a crystallized glass with β-quartz solid solution and/or β-eucryptite precipitated therein, it has a low coefficient of thermal expansion. Furthermore, a low D90/D10 value means that the particle size distribution is narrow (i.e., the particle size distribution is sharp and the particle diameter is fairly uniform). Therefore, when D90/D10 is in a range of 20 or less, the particle size distribution is narrow, so that excellent dispersibility can be achieved. Thus, the filler powder can be homogeneously dispersed in a resin composition, so that a resin composition having an excellent light transmittance can be obtained.

The filler powder according to the present invention preferably has an approximately spherical shape. By doing so, light scattering at the interface between the filler powder and a resin can be reduced. As a result, a resin composition having an excellent light transmittance can be easily obtained.

The filler powder according to the present invention preferably has a specific surface area of 20 m²/g or less.

In the filler powder according to the present invention, a 50% cumulative particle diameter (D50) obtained by measuring the particle size distribution by the laser diffraction and scattering method is preferably 120 μm or less.

The filler powder according to the present invention preferably has a coefficient of thermal expansion of 5×10⁻⁷/° C. or less in a range of 30 to 150° C.

The filler powder according to the present invention preferably has a refractive index nd of 1.48 to 1.62.

The filler powder according to the present invention is preferably made of a crystallized glass containing, in terms of % by mass, 55 to 75% SiO₂, 15 to 30% Al₂O₃, 2 to 10% Li₂O, 0 to 3% Na₂O, 0 to 3% K₂O, 0 to 5% MgO, 0 to 10% ZnO, 0 to 5% BaO, 0 to 5% TiO₂, 0 to 4% ZrO₂, 0 to 5% P₂O₅, and 0 to 2.5% SnO₂.

The filler powder according to the present invention is preferably used by mixing into a resin.

A resin composition according to the present invention contains the above-described filler powder and a resin.

The resin composition according to the present invention preferably has a thickness of 1 mm and a light transmittance of 30% or more at a wavelength of 700 nm.

A method for producing a filler powder according to the present invention includes the steps of: heating a glass powder to melting to form a spherically shaped glass powder; washing the spherically shaped glass powder and then classifying the spherically shaped glass powder; and crystallizing the classified glass powder.

### Advantageous Effects of Invention

The present invention enables provision of a filler powder that has a lower coefficient of thermal expansion than silica powder and can provide a resin composition having an excellent light transmittance.

### DESCRIPTION OF EMBODIMENTS

A filler powder according to the present invention is made of a crystallized glass with β-quartz solid solution (Li₂O.Al₂O₃.nSiO₂; 2<n) and/or β-eucryptite (Li₂O.Al₂O₃.2SiO₂) precipitated therein and has a low thermal expansion characteristic as compared to silica powder commonly used in the past as an inorganic filler powder. Therefore, in mixing the filler powder into a resin, it is possible to achieve a desired thermal expansion characteristic in a relatively small amount.

Furthermore, unlike crystal powders of β-quartz solid solution and β-eucryptite, the filler powder according to the present invention is made of a crystallized glass and therefore has low reactivity with resin. Hence, the filler powder according to the present invention has the feature that when mixed into a resin, the resin is less likely to alter the quality, color, and so on.

The amount of β-quartz solid solution or β-eucryptite precipitated in the filler powder according to the present invention is preferably 50% by mass or more and more preferably 70% by mass or more. If the amount of β-quartz solid solution or β-eucryptite precipitated is too small, the effect of decreasing the coefficient of thermal expansion is difficult to achieve. On the other hand, no particular limitation is placed on the upper limit of the amount of β-quartz solid solution or β-eucryptite precipitated, but it is actually 99% by mass or less. If the filler powder contains both of β-quartz solid solution and β-eucryptite, the total amount of them preferably meets the above range.

The coefficient of thermal expansion of the filler powder according to the present invention in a range of 30 to 150° C. is preferably 5×10⁻⁷/° C. or less, more preferably 3×10-7/° C. or less, and still more preferably 2×10⁻⁷° C. or less. If the coefficient of thermal expansion is too large, a difference in coefficient of thermal expansion between the resin composition and a substrate having an optical semiconductor mounted thereon and sealed with the resin composition promotes the occurrence of cracks. Note that although no particular limitation is placed on the lower limit of the coefficient of thermal expansion, it is actually not less than −30×10⁻⁷/° C.

In the filler powder according to the present invention, the ratio D90/D10 between a 10% cumulative particle diameter (D10) and a 90% cumulative particle diameter (D90) both obtained by measuring the particle size distribution of the filler powder by a laser diffraction and scattering method is 20 or less, preferably 15 or less, and more preferably 10 or less. If D90/D10 is too large, the particle size distribution becomes wide, so that the dispersibility tends to deteriorate. Thus, the filler powder is difficult to homogeneously disperse in a resin composition, so that a resin composition having an excellent light transmittance is difficult to obtain. Although no particular limitation is placed on the lower limit of D90/D10, it is actually not less than 1 and preferably not less than 1.1.

The respective preferred ranges of D10, D50 (50% cumulative particle diameter), and D90 are as follows.

D10 is preferably 70 μm or less, more preferably 60 μm or less, and still more preferably 50 μm or less. D50 is preferably 120 μm or less, more preferably 90 μm or less, and still more preferably 70 μm or less. D90 is preferably 150 μm or less, more preferably 140 μm or less, and still more preferably 130 μm or less. If each of D10, D50, and D90 is too large, the dispersibility tends to deteriorate. No particular limitation is placed on the upper limits of D10, D50, and D90, but, actually, D10 is not less than 0.2 μm, D50 is not less than 0.5 μm, and D90 is not less than 1 μm.

The shape of the filler powder according to the present invention is preferably approximately spherical. By doing so, the specific surface area is reduced even when the particle diameter of the filler powder is small, light scattering at the interface between the filler powder and the resin can be reduced. As a result, a resin composition having an excellent light transmittance can be easily obtained. Note that the above effect can be more easily achieved as the shape is closer to a perfect sphere.

The specific surface area of the filler powder according to the present invention is preferably 20 m²/g or less, more preferably 15 m²/g or less, and still more preferably 10 m²/g or less. If the specific surface area is too large, light scattering at the interface between the filler powder and the resin increases, so that a resin composition having an excellent light transmittance is difficult to obtain. No particular limitation is placed on the lower limit of the specific surface area, but it is actually 0.001 m²/g.

The refractive index nd of the filler powder according to the present invention is preferably 1.48 to 1.62, more preferably 1.5 to 1.6, and still more preferably 1.52 to 1.58. If the refractive index nd is too low or too high, the difference in refractive index from the resin is large, which increases light scattering at the interface between the filler powder and the resin, so that a resin composition having an excellent light transmittance is difficult to obtain.

No particular limitation is placed on the type of the filler powder according to the present invention so long as it can precipitate β-quartz solid solution and/or β-eucryptite. For example, the filler powder according to the present invention is preferably made of a crystallized glass containing, in terms of % by mass, 55 to 75% SiO₂, 15 to 30% Al₂O₃, 2 to 10% Li₂O, 0 to 3% Na₂O, 0 to 3% K₂O, 0 to 5% MgO, 0 to 10% ZnO, 0 to 5% BaO, 0 to 5% TiO₂, 0 to 4% ZrO₂, 0 to 5% P₂O₅, and 0 to 2.5% SnO₂. The reasons why the glass composition range is restricted as above are described below.

SiO₂ is a component that forms the glass network and becomes a constituent of the main crystal. The content of SiO₂ is preferably 55 to 75% and more preferably 60 to 75%. If the content of SiO₂ is too small, the coefficient of thermal expansion tends to increase and the chemical durability tends to decrease. On the other hand, if the content of SiO₂ is too large, the meltability tends to decrease and the viscosity of glass melt tends to increase, which makes it difficult to fine the glass and makes it difficult to form the glass melt into shape.

Al₂O₃ is a component that forms the glass network and becomes a constituent of the main crystal. The content of Al₂O₃ is preferably 15 to 30% and more preferably 17 to 27%. If the content of Al₂O₃ is too small, the coefficient of thermal expansion tends to increase and the chemical durability tends to decrease. On the other hand, if the content of Al₂O₃ is too large, the meltability tends to decrease. Furthermore, the viscosity tends to increase, which makes it difficult to fine the glass and makes it difficult to form the glass melt into shape. In addition, the glass is likely to devitrify.

Li₂O is a constituent of the main crystal and a component that has a significant effect on the crystallinity and decreases the viscosity to improve the meltability and the formability. The content of Li₂O is preferably 2 to 10%, more preferably 2 to 7%, still more preferably 2 to 5%, and particularly preferably 2 to 4.8%. If the content of Li₂O is too small, main crystals become difficult to precipitate and the meltability decreases. Furthermore, the viscosity tends to increase, which makes it difficult to fine the glass and makes it difficult to form the glass melt into shape. On the other hand, if the content of Li₂O is too large, the glass is likely to devitrify.

Na₂O and K₂O are components that decrease the viscosity to improve the meltability and the formability. Each of the respective contents of Na₂O and K₂O is preferably 0 to 3% and more preferably 0.1 to 1%. If the content of Na₂O or content of K₂O is too large, the glass is likely to devitrify and the coefficient of thermal expansion is likely to increase. Furthermore, when the filler powder is mixed into a resin, the resin may alter the quality.

MgO is a component for controlling the coefficient of thermal expansion. The content of MgO is preferably 0 to 5%, more preferably 0.1 to 3%, and still more preferably 0.3 to 2%. If the content of MgO is too large, the glass is likely to devitrify and the coefficient of thermal expansion is likely to increase.

ZnO is a component for controlling the coefficient of thermal expansion. The content of ZnO is preferably 0 to 10%, more preferably 0 to 7%, still more preferably 0 to 3%, and particularly preferably 0.1 to 1%. If the content of ZnO is too large, the glass is likely to devitrify.

BaO is a component for decreasing the viscosity to improve the meltability and the formability. The content of BaO is preferably 0 to 5% and more preferably 0.1 to 3%. If the content of BaO is too large, the glass is likely to devitrify.

TiO₂ and ZrO₂ are components that act as a nucleating agent for precipitating crystals in the crystallization process. The content of TiO₂ is preferably 0 to 5% and more preferably 1 to 4%. The content of ZrO₂ is preferably 0 to 4% and more preferably 0.1 to 3%. If the content of TiO₂ or content of ZrO₂ is too large, the glass is likely to devitrify.

P₂O₅ is a component that promotes phase separation to assist in forming crystal nuclei. The content of P₂O₅ is preferably 0 to 5% and more preferably 0.1 to 4%. If the content of P₂O₅ is too large, the glass is likely to cause phase separation in the melting process, so that the resultant glass is likely to become cloudy.

SnO₂ is a component that acts as a fining agent. The content of SnO₂ is preferably 0 to 2.5% and more preferably 0.1 to 2%. If the content of SnO₂ is too large, the glass is likely to have an excessively dark tone and devitrify.

In addition to the above components, B₂O₃, SrO, CaO, and so on may be appropriately incorporated into the filler powder without impairing the effects of the present invention.

The filler powder according to the present invention may be subjected to surface treatment with a silane coupling agent in order to increase the wettability at the interface with a resin and increase the dispersibility when mixed into the resin. Examples of the silane coupling agent include amino silane, epoxy silane, methacryl silane, ureido silane, and isocyanate silane.

Next, a description will be given of a method for producing a filler powder according to the present invention.

First, a raw material batch obtained by formulating glass raw materials in a predetermined proportion is melted at 1600 to 1800° C. to obtain molten glass. Next, the molten glass is formed into a predetermined shape (for example, a film shape) and then ground and the ground product is classified to obtain a glass powder. The grinding method that can be used is wet grinding or dry grinding, using a ball mill, a bead mill, a jet mill, a vibrating mill or other means. Examples of the classification method that can be used include known classification techniques, such as a wire sieve.

The 50% cumulative particle diameter (D50) of the glass powder is preferably 120 μm or less and more preferably 90 μm or less. If D50 is too large, the production yield of the filler powder is likely to decrease.

The obtained glass powder is heated to melting to form a spherically shaped glass powder. An example of the method for heating the glass powder to melting is a method of feeding the glass powder into a furnace with a table feeder or the like, heating the glass powder at 1400 to 2000° C. to melting with an air burner or the like to form the glass powder into a spherical shape by surface tension, cooling the glass powder, and picking up the glass powder. In the step of forming the glass powder into a spherical shape, vaporizing components contained in the glass powder are turned into fine particles and the fine particles adhere to the glass powder surface. Therefore, the fine particles having adhered to the glass powder surface are washed away and the glass powder is then dried. If in this case the fine particles are not washed away, the fine particles are mixed into a filler powder, so that the particle size distribution is widened and the dispersibility tends to deteriorate. The washing can be performed using a wash fluid, such as water.

Next, the spherically shaped glass powder is classified to obtain a desired particle size distribution. Examples of the classification method that can be used include known classification techniques, such as a wire sieve and an airflow classifier.

Then, the glass powder classified is subjected to heat treatment under predetermined conditions to precipitate therein β-quartz solid solution and/or β-eucryptite, resulting in a filler powder.

As the heat treatment conditions, it is preferred to subject the glass powder to heat treatment at 600 to 800° C. for 1 to 5 hours to form crystal nuclei and then further subject it to heat treatment at 800 to 950° C. for 0.5 to 3 hours to precipitate main crystals. This method can easily provide a filler powder having a high crystallinity.

The filler powder according to the present invention is used, for example, by mixing it into a resin. A resin formed body obtained by mixing the filler powder according to the present invention into a resin is used for an optical semiconductor or so on. No particular limitation is placed on the type of the resin so long as it is commonly used. Examples include thermosetting resins, such as epoxy resin, polyester resin, phenolic resin, urethane resin, and amino resin, and thermoplastic resins, such as polyvinyl resin, polyamide resin, polyimide resin, allyl resin, styrene resin, acrylic resin, and polycarbonate resin.

The content of the filler powder in the resin is appropriately selected according to desired characteristics, such as a coefficient of thermal expansion. For example, the content of the filler powder relative to the total amount of the resin and the filler powder can be appropriately selected preferably in a range of 10 to 95% by mass and more preferably in a range of 20 to 90% by mass.

A resin composition according to the present invention is characterized by containing a resin and the above-described filler powder. The resin composition according to the present invention preferably has a thickness of 1 mm and its light transmittance at wavelengths of 550 nm, 700 nm, and 800 nm is preferably 30% or more, more preferably 40% or more, and still more preferably 50% or more. If the light transmittance is too low, the light extraction efficiency of the optical semiconductor is likely to decrease. No particular limitation is placed on the upper limit of the light transmittance, but it is actually 99% or less.

### EXAMPLES

Hereinafter, the present invention will be described with reference to examples, but is not limited to the examples.

Table 1 shows examples according to the present invention (Samples Nos. 1 to 5) and comparative examples (Samples Nos. 6 to 8).

TABLE 1

| | | | No. 1 | No. 2 | No. 3 | No. 4 | No. 5 | No. 6 | No. 7 | No. 8 |
|---|---|---|---|---|---|---|---|---|---|---|
| Filler Powder | Glass composition | SiO2 | 66 | | | | | | | 100 |
| | (% by mass) | A12O3 | 22 | | | | | | | |
| | | BaO | 1.5 | | | | | | | |
| | | Li2O | 4 | | | | | | | |
| | | Na2O | 0.5 | | | | | | | |
| | | K2O | 0.5 | | | | | | | |
| | | TiO2 | 2 | | | | | | | |
| | | ZrO2 | 2 | | | | | | | |
| | | P2O5 | 1.3 | | | | | | | |
| | | SnO2 | 0.2 | | | | | | | |
| | Particle diameter | D10 | 0.7 | 0.9 | 0.7 | 16.1 | 46 | 0.8 | 1.7 | 0.7 |
| | (μm) | D50 | 1.3 | 2.2 | 3 | 31.3 | 61 | 4.9 | 23.9 | 3.8 |
| | | D90 | 2.3 | 4.2 | 6.5 | 59.2 | 73 | 17.9 | 58 | 11.9 |

| | D90/D10 | 3.3 | 4.7 | 9.3 | 3.7 | 1.6 | 22.4 | 34.1 | 17.0 |
|---|---|---|---|---|---|---|---|---|---|
| | SSA (m²/g) | 11.6 | 6 | 2 | 1.5 | 0.05 | 1.5 | 0.56 | 3.1 |
| | CTE (×10⁷/° C.) | −11 | | | | | | | 6 |
| | Refractive index nd | 1.54 | | | | | | | 1.53 |
| Resin Composition | Light transmittance (%) | 54 | 55 | 60 | 68 | 71 | 16 | 26 | 39 |
| | CTE (×10⁻⁷/° C.) | 710 | 700 | 690 | 700 | 700 | 710 | 710 | 840 |

(1) Filler Powder

Raw material powders were formulated to give each of the compositions shown in the table and uniformly mixed. Each of the obtained raw material batches was melted at 1600 to 1800° C. until it became homogeneous, the melt was then run through between a pair of roller to form it into a film, the film was ground, and the ground product was classified with a wire sieve, thus obtaining a glass powder having particle diameters shown in the table. As for Sample No. 8, a filler powder made of silica glass was used.

The obtained glass powder was fed into a furnace with a table feeder, heated at 1400 to 2000° C. to melting with an air burner to form the glass powder into a spherical shape.

Next, fine particles having adhered to the glass powder surface were washed away with water and the glass powder was then dried.

Subsequently, the spherically shaped glass powder was classified with an airflow classifier to give particle diameters described in the table.

Then, the glass powder classified was subjected to heat treatment at 600 to 800° C. for 1.5 hours to form crystal nuclei and then further subjected to heat treatment at 900 to 950° C. for an hour to crystallize the glass powder, thus obtaining a filler powder. When the precipitated crystals of Samples Nos. 1 to 7 were analyzed, it was confirmed that β-quartz solid solution precipitated as a main crystal.

The obtained filler powders were measured in terms of specific surface area (SSA), coefficient of thermal expansion (CTE), and refractive index nd. The results are shown in the table.

Samples Nos. 1 to 5, which were examples of the present invention, exhibited a ratio D90/D10 as small as 1.6 to 9.3, i.e., a narrow particle size distribution, and exhibited a coefficient of thermal expansion as low as −11×10⁻⁷/° C. In contrast, Samples Nos. 6 and 7, which were comparative examples, exhibited a ratio D90/D10 as large as 22.4 or more, i.e., a wide particle size distribution. Sample No. 8 exhibited a coefficient of thermal expansion as high as 6×10⁻⁷/° C.

The specific surface area was measured with a BET measuring device.

The coefficient of thermal expansion in a range of 30 to 150° C. was measured with a TMA. Each sample for thermal expansion measurement was produced by forming the molten glass into a sheet, then subjecting the glass sheet to heat treatment at 600 to 800° C. for 1.5 hours to form crystal nuclei and then further subjecting it to heat treatment at 900 to 950° C. for an hour to crystallize the glass sheet.

The refractive index nd was measured with a refractometer.

(2) Resin Composition

An epoxy-based thermosetting resin (refractive index nd: 1.54, coefficient of thermal expansion in a range of 30 to 150° C.: 1500×10⁻⁷/° C.) and each of the filler powders were mixed in a proportion of, in terms of % by mass, 40% to 60% and the mixture was kneaded with a three-roller mixer, thus obtaining a resin composition. The obtained resin composition was sandwiched between two glass slides so that the resin composition had a thickness of 1 mm, and subjected to heat treatment at 120° C. for six hours to cure the resin composition. Thus, a resin composition with a thickness of 1 mm was obtained.

The obtained resin composition was measured in terms of light transmittance and coefficient of thermal expansion (CTE). The results are shown in the table.

Samples Nos. 1 to 5, which were examples of the present invention, exhibited a light transmittance as high as 54% or more and exhibited a coefficient of thermal expansion as low as 710×10⁻⁷/° C. or less. In contrast, Samples Nos. 6 and 7, which were comparative examples, exhibited a light transmittance as low as 26% or less since the filler powder had a large ratio D90/D10, i.e., a wide particle size distribution. Sample No. 10 exhibited a coefficient of thermal expansion of the resin composition as high as 840×10⁻⁷/° C. since the coefficient of thermal expansion of the filler powder was as high as 6×10⁻⁷/° C.

The light transmittance was measured with a spectro-photometer.

The coefficient of thermal expansion in a range of 30 to 150° C. was measured with a TMA.

1. A filler powder made of a crystallized glass with β-quartz solid solution and/or β-eucryptite precipitated therein, wherein a ratio D90/D10 between a 10% cumulative particle diameter (D10) and a 90% cumulative particle diameter (D90) both obtained by measuring a particle size distribution of the filler powder by a laser diffraction and scattering method is 20 or less.

2. The filler powder according to claim 1, having an approximately spherical shape.

3. The filler powder according to claim 1, having a specific surface area of 20 m²/g or less.

4. The filler powder according to claim 1, wherein a 50% cumulative particle diameter (D50) obtained by measuring the particle size distribution by the laser diffraction and scattering method is 120 μm or less.

5. The filler powder according to claim 1, having a coefficient of thermal expansion of 5×10⁻⁷/° C. or less in a range of 30 to 150° C.

6. The filler powder according to claim 1, having a refractive index nd of 1.48 to 1.62.

7. The filler powder according to claim 1, being made of a crystallized glass containing, in terms of % by mass, 55 to 75% SiO₂, 15 to 30% Al₂O₃, 2 to 10% Li₂O, 0 to 3% Na₂O, 0 to 3% K₂O, 0 to 5% MgO, 0 to 10% ZnO, 0 to 5% BaO, 0 to 5% TiO₂, 0 to 4% ZrO₂, 0 to 5% P₂O₅, and 0 to 2.5% SnO₂.

8. The filler powder according to claim 1, being used by mixing into a resin.

9. A resin composition containing the filler powder according to claim 1 and a resin.

10. The resin composition according to claim 9, having a thickness of 1 mm and a light transmittance of 30% or more at a wavelength of 700 nm.

11. A method for producing a filler powder, the method comprising the steps of: heating a glass powder to melting to form a spherically shaped glass powder; washing the spherically shaped glass powder and then classifying the spherically shaped glass powder; and crystallizing the classified glass powder.
